(19) United States
(12) Patent Application Publication
(10) Pub. No.: US 2026/0071830 A1
(43) Pub. Date: Mar. 12, 2026

(54) WATER BLOCK STRUCTURE

(71) Applicant: ASIA VITAL COMPONENTS (CHINA) CO., LTD., Shenzhen (CN)

(72) Inventors: Xue-Hui Liu, Shenzhen (CN); Jiu-Ming Chen, Shenzhen (CN); Min-Jian Deng, Shenzhen (CN)

(21) Appl. No.: 18/894,624

(22) Filed: Sep. 24, 2024

(30) Foreign Application Priority Data
Sep. 12, 2024 (TW) 113134697

(51) Int. Cl. F28F 3/06

(52) U.S. Cl. CPC F28F 3/06; F28F 2220/00; F28F 2230/00

(57) ABSTRACT

A water block structure with upgraded heat dissipation efficiency includes vertically stacked top cover, intermediate plate and heat sink. The intermediate plate and the heat sink together define a heat exchange chamber communicable with first and second passages on the intermediate plate and internally provided with fins. The fins are transversely extended and spaced to form a transverse flow passage between any two adjacent fins. A middle portion of the transverse flow passages corresponding to the first passage; and a peripheral flow passage communicable with end portions of the transverse flow passages and located corresponding to the second passages is formed around the fins. A working fluid flows downward into the heat exchange chamber via the first passage to flow through the transverse flow passages and the peripheral flow passage while sufficiently contact with all the fins before flowing upward via the second passages to leave the water block structure.

This application claims the priority benefit of Taiwan patent application number 113134697 filed on Sep. 12, 2024, the disclosure of which is hereby incorporated by reference in its entirety.

### FIELD OF THE INVENTION

The present invention relates to a water cooling structure, and more particularly to a water block structure enabling upgraded heat exchange efficiency.

### BACKGROUND OF THE INVENTION

A conventional liquid-cooling type heat dissipation system mainly consists of a plurality of serially connected pipes, water blocks, and pumps; or cooling modules (such as water cooling radiators). Among others, the water blocks are in contact with heat-producing elements to assist in dissipating heat from the heat-producing elements.

A prior art water block internally defines a heat exchange chamber, through which a working fluid flows; and the heat exchange chamber is internally provided with a plurality of heat radiation fins. The fins absorb heat produced by heat-producing elements and the absorbed heat is transferred to the working fluid flowing through the heat exchange chamber, so that the heat is finally carried away from the heat-producing elements by the working fluid to achieve the purpose of heat dissipation. Specifically, the prior art water block includes at least an upper cover and a lower case, which together define the heat exchange chamber between them. The fins in the heat exchange chamber provide increased heat dissipation areas and any two adjacent fins have a flow passage defined between them for the working fluid to flow therethrough. The upper cover and the lower case of the prior art water block are provided with an inlet and an outlet, respectively. The working fluid flows into or out of the heat exchange chamber of the water block via the inlet and the outlet, respectively.

Since the heat exchange chamber in the prior art water block is a flow path having only one single layer, a large part of the working fluid flowing into the heat exchange chamber via the inlet only flows through the surfaces of an upper portion of the finned heat exchange chamber and then quickly flows out of the water block, and there is not any effective thermal convection taking place in the fluid that is located at a lower portion of the heat exchange chamber, such as in the flow passages formed between the adjacent fins, and has a relatively high temperature. Or, some part of the working fluid is not well guided and forms turbulence in the heat exchange chamber to cause heat accumulation and accordingly, result in poor heat exchange efficiency of the prior art water block.

It is therefore tried by the inventor to develop an improved water block structure to overcome the problems found in the prior art water block.

### SUMMARY OF THE INVENTION

A primary object of the present invention is to provide a water block structure that can solve the above problems by allowing a working fluid to flow through the water block structure that internally includes a flow path having a vertical depth and a defining a horizontally one-direction flowing direction, such that the working fluid can pass through every location of the flow path to have increased contact areas and time for sufficient heat transfer to achieve largely upgraded heat exchange efficiency.

To achieve the above and other objects, the present invention provides a water block structure that includes a top cover, an intermediate plate, and a heat sink.

The top cover is provided with a first opening and a second opening, which extend through the top cover from an upper side to a lower side thereof and are located spaced from each other.

The intermediate plate has an upper side, to which the top cover is connected. The intermediate plate is provided with a first passage and at least one second passage, which are located corresponding to the first and the second opening, respectively, and penetrate through the intermediate plate in a thickness direction thereof.

The heat sink is assembled to a lower side of the intermediate plate; and the heat sink and the intermediate plate together define and seal a heat exchange chamber that is communicable with the first and the second passage. The heat sink has a heat dissipation side facing toward the intermediate plate and a heat absorption side located opposite to the heat dissipation side. The heat dissipation side is provided with a plurality of transversely extended fins that are protruded into the heat exchange chamber and parallelly spaced from each other, such that a transverse flow passage is formed between any two adjacent fins. The first passage axially extends across a top of the transverse flow passages, and a portion of the transverse flow passages corresponding to the first passage forms a first interchange zone, while two end portions of the transverse flow passages form a second interchange zone each. The second interchange zones are communicable with a peripheral flow passage located around the fins, and the at least one second passage is correspondingly located above the peripheral flow passage.

With the above arrangements, a working fluid can be supplied into the water block structure via one of the first and the second opening. The working fluid then passes through the intermediate plate via the first passage or the second passages to flow into the heat exchange chamber. The working fluid is subjected to a pressure and is accordingly continuously pushed to flow through the transverse flow passages. Thereafter, the working fluid flows upward into the other one of the first and the second passage and finally flows out of the water block structure via the other one of the first and the second opening on the top cover that is not used to supply the working fluid, so as to complete one cycle of flow path in one direction.

With the above described flow path for the water block structure of the present invention, the working fluid can be otherwise supplied into the water block structure via the other one of the first and second opening and then flows along another one-direction flow path reverse to the above described one and passes the intermediate plate into the heat exchange chamber. The incoming working fluid is pushed by a stable pressure to continuously and thoroughly flow through every location of the transverse flow passages between the adjacent fins, enabling increased contact areas and time between the working fluid and the fins for transferring heat. Therefore, the water block structure of the present invention has largely upgraded heat dissipation efficiency to avoid heat accumulation in the water block structure.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an assembled perspective view of a water block structure according to a first embodiment of the present invention;

FIG. 2 is an exploded top view of FIG. 1;

FIG. 3 is an exploded bottom view of FIG. 1;

FIG. 4 is a sectional side view of FIG. 1;

FIG. 5 is a top view of FIG. 1 showing the flow path of a working fluid in the water block structure of the present invention; and

FIG. 6 is an exploded bottom perspective view of a water block structure according to a second embodiment of the present invention.

### DETAILED DESCRIPTION OF THE PREFERRED EMBODIMENTS

The present invention will now be described with some preferred embodiments thereof. For the purpose of easy to understand, elements that are the same in the preferred embodiments are denoted by the same reference numerals.

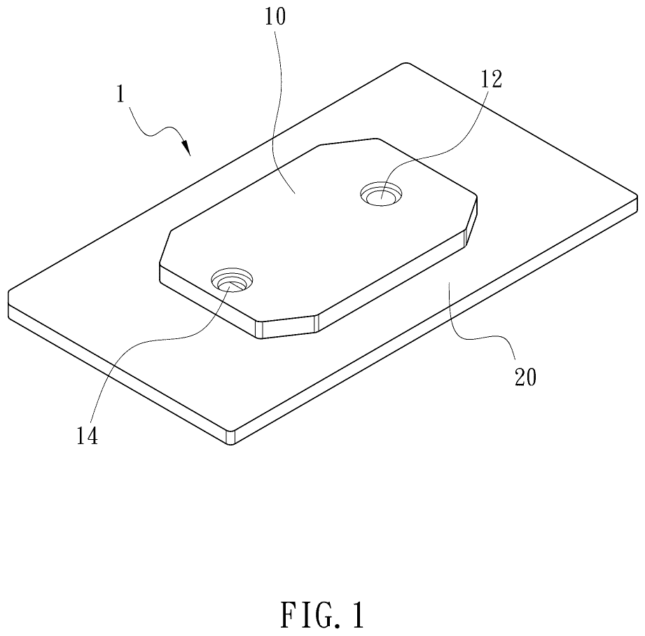

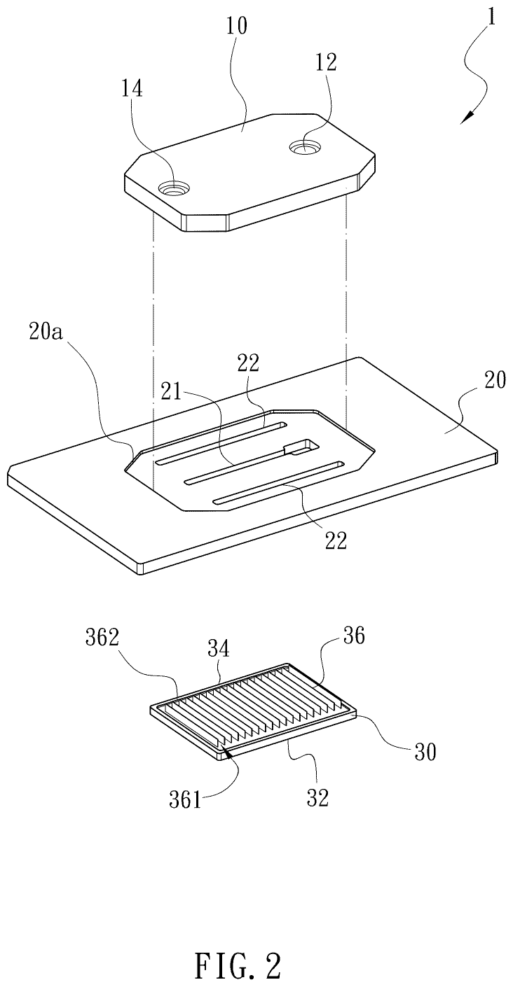

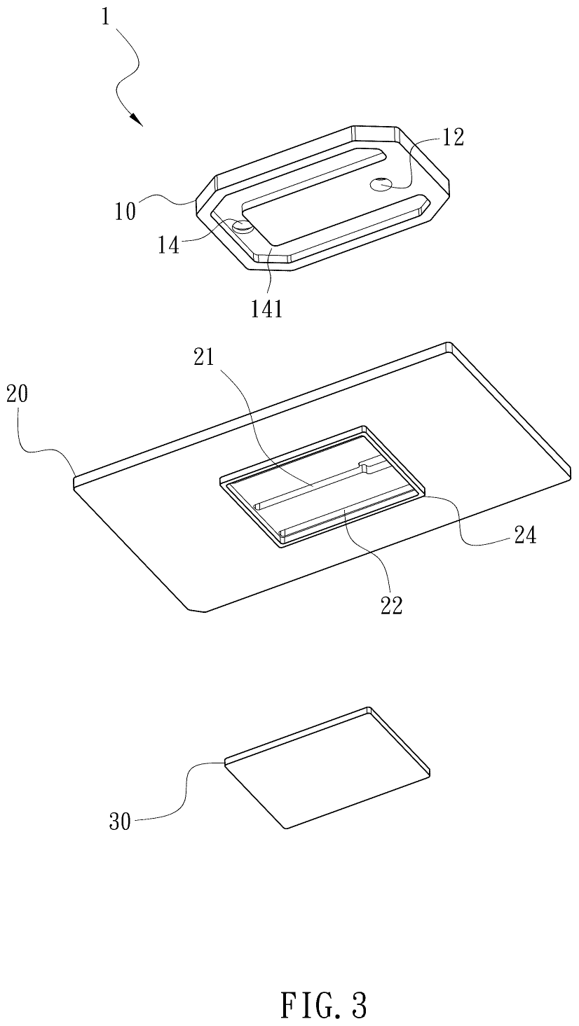

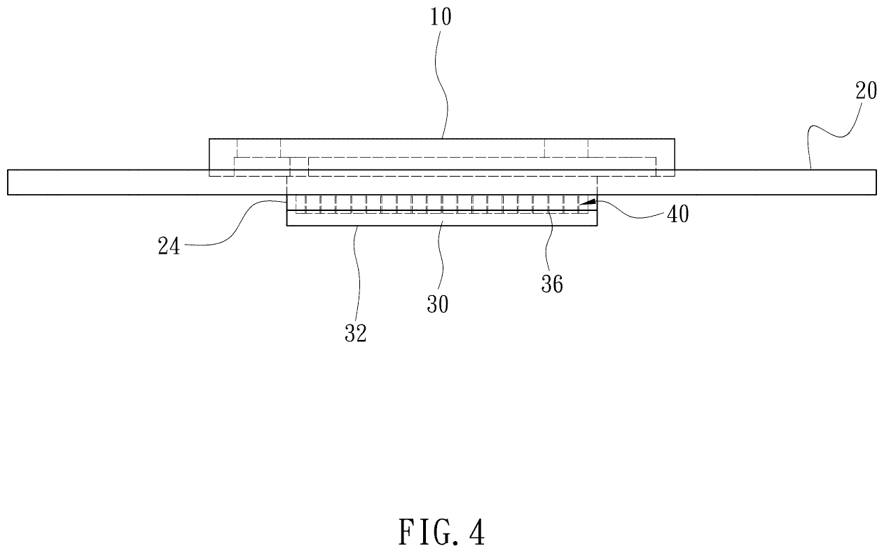

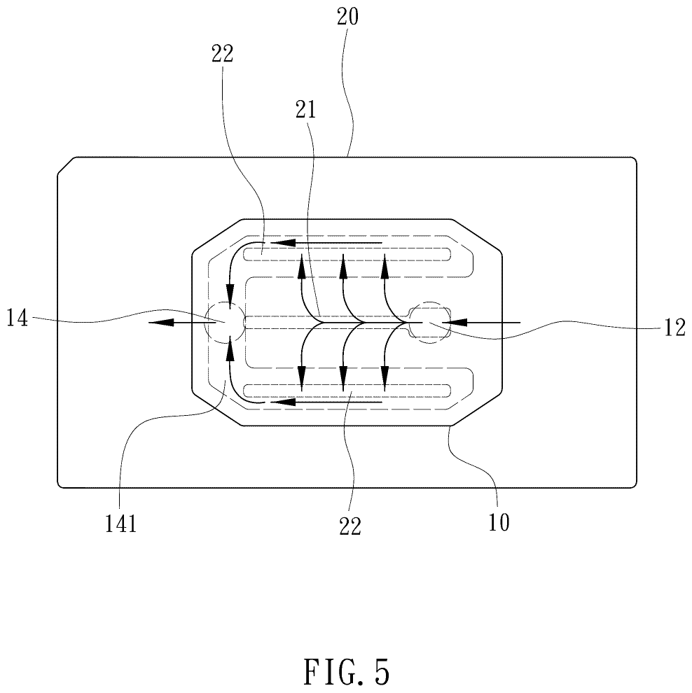

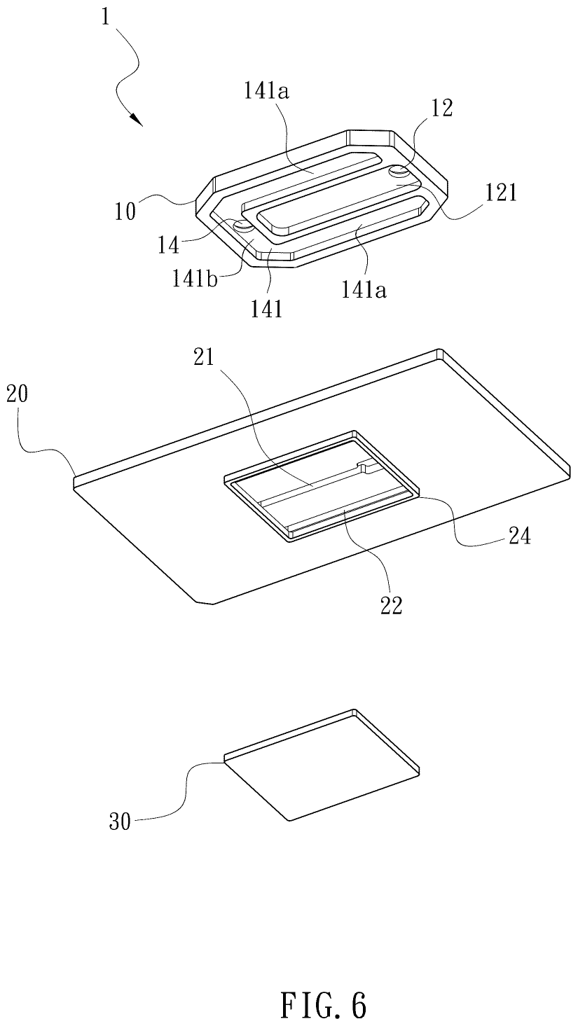

FIG. 1 is an assembled perspective view of a water block structure 1 according to a first embodiment of the present invention, FIGS. 2 and 3 are exploded top and bottom views, respectively, of FIG. 1, FIG. 4 is a sectional side view of FIG. 1, FIG. 5 is a top view of FIG. 1 showing the flow path of a working fluid in the water block structure of the present invention, and FIG. 6 is an exploded bottom perspective view of a water block structure 1 according to a second embodiment of the present invention.

Please refer to FIGS. 1 to 3 at the same time. A water block structure 1 according to a first embodiment of the present invention includes a top cover 10, an intermediate plate 20, and a heat sink 30, which are stacked from top to bottom. The heat sink 30 located at the bottom absorbs heat from a heat source (not shown) and the absorbed heat can be fully and thoroughly transferred to and carried away by the working fluid that flows through a multi-layer three-dimensional (3D) and deep flow path in the water block structure 1.

As can be seen in FIGS. 2 and 3, the top cover 10 is provided with a first opening 12 and a second opening 14 that are spaced from each other and extended through the top cover 10 from an upper side to a lower side thereof, such that the first and the second opening 12, 14 are independent of and separated from each other. A working fluid supplying or recycling connector or pipe (not shown) is connected to each of the first and the second opening 12, 14 on the upper side of the top cover 10. Depending on actual need, one of the first opening 12 and the second opening 14 is used as an inlet of the working fluid while the other one as an outlet of the working fluid, so that the working fluid can flow through the water block structure 1 in one of two reversed directions. With the above arrangements, the working fluid can be guided to flow into and out of the water block structure 1 along a predetermined flow path in one direction.

As shown in FIG. 3, the top cover 10 is provided on the lower side with a peripheral guiding channel 141 that is recessed into the lower side of the top cover 10 and communicable with the second opening 14. The peripheral guiding channel 141 provides a storage space for the working fluid that is about to be drained from or supplied into the water block structure 1 of the present invention. Substantially, the peripheral guiding channel 141 is extended around and recessed into the periphery of the lower side of the top cover 10.

Please refer to FIGS. 2 and 3 at the same time. The lower side of the top cover 10 is correspondingly connected to an upper side of the intermediate plate 20. That is, the intermediate plate 20 has the top cover 10 assembled to the upper side thereof. For example, the intermediate plate 20 may be formed on the upper side with a sunken limiting recess 20a for the top cover 10 to correspondingly set in the limiting recess 20a. However, the top cover 10 can be connected to the limiting recess 20a in other possible way. Further, the intermediate plate 20 is provided at positions corresponding to the first opening 12 and the second opening 14 with a first passage 21 and two second passages 22, which penetrate through the intermediate plate 20 to a lower side thereof.

For instance, the first passage 21 can be formed on the intermediate plate 20 corresponding to the first opening 12 on the top cover 10. When the working fluid is supplied into the water block structure 1 via the first opening 12, the working fluid would be guided to pass through the first passage 21 and flows downward under pressure. Meanwhile, the working fluid flowing toward the second opening 14 at this point would also be guided to flow upward into the second passages 22 or the peripheral guiding channel 141 under pressure and then be drained via the second opening 14. That is, the working fluid passing through the intermediate plate 20 from two different directions will flow along the same flow path but in two reversed directions.

FIG. 6 is an exploded bottom perspective view of a water block structure 1 according to a second embodiment of the present invention. In the second embodiment, the top cover 10 is provided additionally on the lower side with a longitudinal guiding channel 121, which is recessed into the lower side of the top cover 10 and communicable with the first opening 12. For example, the longitudinal guiding channel 121 is linearly extended on the lower side of the top cover 10 along a major or longer central axis thereof. It is to be noted that, since the flow path corresponding to the first opening 12 are in a direction reversed to that of the flow path corresponding to the second opening 14, the longitudinal guiding channel 121 is separated from and independent of the peripheral guiding channel 141 and is located corresponding to and communicable with the first passage 21 on the intermediate plate 20. For example, the first passage 21 is also extended longitudinally on the intermediate plate 20. Further, the longitudinal guiding channel 121 has a flow path width larger than a passage width of the first passage 21.

In the second embodiment, the peripheral guiding channel 141 is located corresponding to and communicable with the second passages 22 on the intermediate plate 20. The peripheral guiding channel 141 consists of two flow guidance sections 141a and a flow convergence section 141b. The two flow guidance sections 141a are separately located at two lateral sides of and independently spaced from the longitudinal guiding channel 121 to extend substantially in parallel with each other. The flow convergence section 141b is transversely communicable with the two flow guidance sections 141a and communicates with the second opening 14. The working fluid is guided by the flow guidance sections 141a to eventually flow out of the water block structure 1 via the second opening 14. It is understood the working fluid is not necessarily guided out of the water block structure 1 along the above flow path. Similarly, the peripheral guiding channel 141 has a flow path width larger than a passage width of the second passages 22.

In the present invention, with the intermediate plate 20, the working fluid can flow into or out of the first passage 21 and the second passages 22 that have different passage widths, so that the working fluid is controlled to flow forward stably along a predetermined flowing direction.

As shown in FIG. 4, the heat sink 30 is assembled to the lower side of the intermediate plate 20. The intermediate plate 20 and the heat sink 30 together define and seal a heat exchange chamber 40 between them. The heat exchange chamber 40 is communicable with the first passage 21 and the second passages 22, and the working fluid can flow downward into the heat exchange chamber 40. As shown in FIGS. 2 and 3, the intermediate plate 20 may further include a downward protruded wall portion 24, which cooperates with the heat sink 30 to define and seal the heat exchange chamber 40. In other embodiments, the heat sink 30 may be provided with a protruded wall portion (not shown) for engaging with a groove (not shown) provided on the lower side of the intermediate plate 20.

In the heat exchange chamber 40, the heat produced by the heat source (such as an electronic element) and absorbed by the heat sink 30 is transferred to the working fluid and carried away. More specifically, as described above, when the working fluid is guided into the heat exchange chamber 40 via the first passage 21, the working fluid is subjected to a pressure and pushed forward to complete cone cycle of circulation in the heat exchange chamber 40 in one direction and eventually passes through the second passages 22 to flow out of the heat exchange chamber 40. Alternatively, the working fluid may flow into the heat exchange chamber 40 via the second passages 22 to flow forward in a reversed direction and eventually flow out of the heat exchange chamber 40 via the first passage 21.

The heat sink 30 has a heat dissipation side 34 facing toward the intermediate plate 20, and a heat absorption side 32 located opposite to the heat dissipation side 34. In practical application of the water block structure 1, the heat source is in tight contact with the heat absorption side 32 at a lower side of the heat sink 30, and the heat absorbed by the heat sink 30 is transferred to the heat dissipation side 34. The heat sink 30 includes a plurality of heat radiation fins 36 provided on the heat dissipation side 34. The fins 36 are extended transversely to protrude into the heat exchange chamber 40 and are parallelly spaced from each other to form a flow passage 361 between any two adjacent fins 36. For example, when the working fluid flows through the first passage 21 down into the heat exchange chamber 40 (or, the working fluid may otherwise flow into the heat exchange chamber 40 via the second passages 22, depending on the flowing direction of the working fluid), the working fluid is guided by the transverse flow passages 361 to flow in the heat sink 30.

As can be seen in FIG. 2, the first passage 21 extends across a top of a middle portion of the transverse flow passages 361, such that a first interchange zone is formed at the middle portion of the transverse flow passages 361 at where the first passage 21 extends perpendicular to the fins 36, and a second interchange zone is formed at each of two opposite end portions of the transverse flow passages 361.

For example, in the case the working fluid flows into the first passage 21 first, the working fluid will fall straight down under a pressure. The working fluid reaches at the first interchange zone at the middle portion of the transverse flow passages 361 and keeps flowing deeper into lower parts of the transverse flow passages 361. The working fluid then flows from the middle portion toward two opposite end portions of the transverse flow passages 361 to fully contact with the surfaces of all the fins 36 and absorb heat from the fins 36. Meanwhile, the working fluid flowing in the same direction into the transverse flow passages 361 and absorbed heat to have a relatively high temperature is forced to keep flowing and circulate. Further, the second interchange zones are correspondingly communicable with a peripheral flow passage 362 formed around the fins 36. The peripheral flow passage 362 is located corresponding to at least one of the second passages 22 located above it. Since the working fluid in the second interchange zones at two opposite end portions of the transverse flow passages 361 is continuously pushed by the working fluid from the first interchange zone, the working fluid flows into the peripheral flow passage 362, which is communicable with the second interchange portions and located corresponding to the second passages 22. And then, the working fluid is further pushed upward into the second passages 22 to flow back.

In the same principle, the working fluid may otherwise flow into the second opening 14 first. In this case, the working fluid will flow along a flow path that is reversed to the above-described flow path to complete one cycle of circulation in one direction and finally flows out of the water block structure 1 via the first opening 12. In the process of circulation, the working fluid is also subjected to a sufficient pressure and pushed to flow forward to achieve the same heat exchange effect. Therefore, with the present invention, the working fluid can flow through the whole flow path in one direction to avoid the problems of forming turbulence and incomplete heat exchange. Meanwhile, the present invention enables increased contact areas and time between the working fluid and the fins 36. Particularly, with the vertically stacked top cover 10, intermediate plate 20 and heat sink 30 from top to bottom, the working fluid is constantly subjected to sufficient pressure to flow straight down from the top cover 10 and push the working fluid flowing through the fins 36 to circulate, so that the circulation efficiency is effectively upgraded to avoid heat accumulation.

Specifically, as shown in FIG. 6, in the case there is provided a longitudinal guiding channel 121 extending along a major central axis of the intermediate plate 20, the intermediate plate 20 may have two second passages 22 parallelly located at two lateral sides of the first passage 21. Meanwhile, the peripheral guiding channel 141 includes two flow guidance sections 141a corresponding to the two second passages 22 and extending in parallel with the longitudinal guiding channel 121. The peripheral flow passage 362 in the heat exchange chamber 40 is located corresponding to and communicable with the second interchange zones at two lateral sides of the transverse flow passage 361. With these arrangements, the working fluid can be guided to flow upward out of or to flow downward into the water block structure 1 all in one direction to complete one cycle of circulation.

It is to be noted that, in the present invention, the working fluid flowing through the heat sink 30 is always flowing in one direction to pass through all the surfaces of the fins 36, it is therefore possible to increase the contact areas and the contact time between the working fluid and the fins 36 to achieve completed heat transfer without causing turbulence in the working fluid to result in inefficient heat dissipation effect. Further, in the present invention, the fins 36 have the functions of enhancing heat exchange, enhancing the circulation efficiency of the working fluid, and enabling good guiding of the working fluid to always flow in one direction.

Please refer to FIG. 5. The water block structure 1 of the present invention enables the working fluid to flow along a predetermined flow path in one direction. For example, the working fluid flows through the first opening 12 and the intermediate plate 20 into the heat exchange chamber 40 sequentially. In the heat exchange chamber 40, the working fluid flows from the first interchange zone into the transverse flow passages 361 and the second interchange zones at the end portions of the transverse flow passages 361, and then flows from the second interchange zones into to the peripheral flow passage 362. The working fluid in the peripheral flow passage 362 is continuously pushed under pressure to pass through the second passages 22 that are located above and corresponding to the peripheral flow passage 362. Finally, the working fluid converges at the second opening 14 that is communicable with the second passages 22 and then flows out of the water block structure 1 via the second opening 14. Alternatively, the working fluid may otherwise flow into the water block structure 1 via the second opening 14 and then flows along a flow path that is reversed to the above-described flow path. With these arrangements, the working fluid enters the heat exchange chamber 40 of the water block structure 1 of the present invention to flow in a regular direction for carrying heat away from the fins 36. With the vertically stacked top cover 10, intermediate plate 20, and the heat sink 30, the working fluid is constantly subjected to a stable pressure and pushed to fully contact with every location of the fins 36 of the heat sink 30, which not only pushes the working fluid to circulate in the water cooling system, but also allows the working fluid to have increased contact areas and contact time with the fins 36 to thoroughly carry the heat away from the fins 36. Therefore, the heat exchange efficiency can be effectively upgraded to avoid heat from accumulating in the heat exchange chamber 40.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A water block structure, comprising:
a top cover being provided with a first opening and a second opening, which extend through the top cover from an upper side to a lower side thereof;
an intermediate plate having an upper side, to which the top cover is connected; the intermediate plate being provided with a first passage and at least one second passage corresponding to the first and the second opening, respectively, and the first and the second passages penetrating through the intermediate plate in a thickness direction thereof; and
a heat sink being assembled to a lower side of the intermediate plate; the heat sink and the intermediate plate together defining and sealing a heat exchange chamber that is communicable with the first and the second passage; the heat sink having a heat dissipation side facing toward the intermediate plate and a heat absorption side located opposite to the heat dissipation side; the heat dissipation side being provided with a plurality of transversely extended fins protruded into the heat exchange chamber and parallelly spaced from each other, such that a transverse flow passage is formed between any two adjacent fins; the first passage axially extending across a top of the transverse flow passages, and a portion of the transverse flow passages corresponding to the first passage forming a first interchange zone, while two end portions of the transverse flow passages forming a second interchange zone each; the second interchange zones being communicable with a peripheral flow passage located around the fins, and the peripheral flow passage being located corresponding to the at least one second passage located above the peripheral flow passage.

2. The water block structure as claimed in claim 1, wherein the top cover is further provided on the lower side with a longitudinal guiding channel, which is recessed into the lower side of the top cover and communicable with the first opening; the longitudinal guiding channel being corresponding to and communicable with the first passage on the intermediate plate; the first passage being extended longitudinally, and the longitudinal guiding channel having a flow path width larger than a passage width of the first passage.

3. The water block structure as claimed in claim 2, wherein the top cover is further provided on the lower side with a peripheral guiding channel, which is recessed into the lower side of the top cover and communicable with the second opening; the peripheral guiding channel being corresponding to and communicable with the at least one second passage on the intermediate plate, and the peripheral guiding channel having a flow path width larger than a passage width of the at least one second passage.

4. The water block structure as claimed in claim 3, wherein the peripheral guiding channel includes two flow guidance sections located at two lateral sides of the longitudinal guiding channel, and a flow convergence section transversely communicable with the two flow guidance sections and communicable with the second opening.

5. The water block structure as claimed in claim 4, wherein the intermediate plate is provided with two second passages located at two lateral sides of the first passage corresponding to the two flow guidance sections of the peripheral guiding channel on the lower side of the top cover; and the two second passages also being located corresponding to portions of the peripheral flow passage in the heat exchange chamber that communicate with the end portions of the transverse flow passages.

6. The water block structure as claimed in claim 1, wherein the intermediate plate is provided on the upper side with a limiting recess for the lower side of the top cover to correspondingly engage with.

7. The water block structure as claimed in claim 1, wherein the intermediate plate is provided on the lower side with a downward protruded wall portion, and the protruded wall portion and the heat sink together define and seal the heat exchange chamber.
